(19) United States
(12) Patent Application Publication
(10) Pub. No.: US 2013/0206566 A1
(43) Pub. Date: Aug. 15, 2013

(54) CAPACITIVE TOUCH DEVICE

(71) Applicant: Chih-Chung Lin, Taipei City (TW)

(72) Inventor: Chih-Chung Lin, Taipei City (TW)

(73) Assignee: Chih-Chung Lin, Taipei City (TW)

(21) Appl. No.: 13/442,871

(22) Filed: Apr. 10, 2012

(30) Foreign Application Priority Data
Feb. 15, 2012 (TW) 101104870

(51) Int. Cl. H03K 17/975

(52) U.S. Cl. 200/600

(57) ABSTRACT

A capacitive touch device includes a first transparent substrate, a second transparent substrate and an adhesive layer connecting the first and second transparent substrates with each other. The first transparent substrate has a first side and a second side. A first conductive layer is disposed on the second side. The second transparent substrate has a third side and a fourth side. A second conductive layer is selectively disposed on the third side or the fourth side. The adhesive layer is disposed between the first transparent substrate and the second transparent substrate. By means of the design of the capacitive touch device, the thickness of the touch device is greatly reduced and the manufacturing cost is lowered.

This application claims the priority benefit of Taiwan patent application number 101104870 filed on Feb. 15, 2012.

### BACKGROUND OF THE INVENTION

1. Field of the Invention

The present invention relates generally to a capacitive touch device, and more particularly to a capacitive touch device, which can greatly reduce the thickness of the capacitive touch panel and lower the manufacturing cost.

2. Description of the Related Art

In recent years, following the development of touch panel technique, various portable electronic devices with display function, such as intelligent cellular phones, tablets and MP5, have employed touch panels instead of the conventional mechanical pushbuttons that occupy much room.

In the conventional touch panels, both the single-board touch panel and the double-board touch panel are made of transparent conductive substrates by means of several times of halftone print processes or lithography processes. The transparent conductive substrate is generally made of glass. The unit price of the transparent conductive substrate is quite high. Moreover, in manufacturing, much material is wasted. In case that a defective product is produced in the manufacturing process, it is necessary to discard the entire touch panel without possibility of recovery. This results in waste of cost.

Besides, the lithographic equipment is quite expensive so that the production cost will be inevitably increased as a whole. Moreover, the composition and developer used in the lithography process are both chemical solutions harmful to human bodies. Therefore, the composition and developer used in the lithography process not only will seriously threaten the health of the operators on the scene, but also will lead to serious contamination of ecological environment.

### SUMMARY OF THE INVENTION

A primary object of the present invention is to provide a capacitive touch device, which can lower the manufacturing cost.

A further object of the present invention is to provide the above capacitive touch device, which can greatly reduce the total thickness of the touch device.

To achieve the above and other objects, the capacitive touch device of the present invention includes a first transparent substrate, a second transparent substrate and an adhesive layer. The first transparent substrate has a first side and a second side opposite to the first side. A first conductive layer is disposed on the second side. The second transparent substrate has a third side and a fourth side opposite to the third side. A second conductive layer is selectively disposed on the third side or the fourth side. The adhesive layer is disposed between the first transparent substrate and the second transparent substrate to connect the first and second transparent substrates with each other. By means of the design of the capacitive touch device of the present invention, the thickness of the touch device is greatly reduced and the manufacturing cost is lowered.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a sectional view of a first embodiment of the capacitive touch device of the present invention; and

FIG. 2 is a sectional view of a second embodiment of the capacitive touch device of the present invention.

### DETAILED DESCRIPTION OF THE PREFERRED EMBODIMENTS

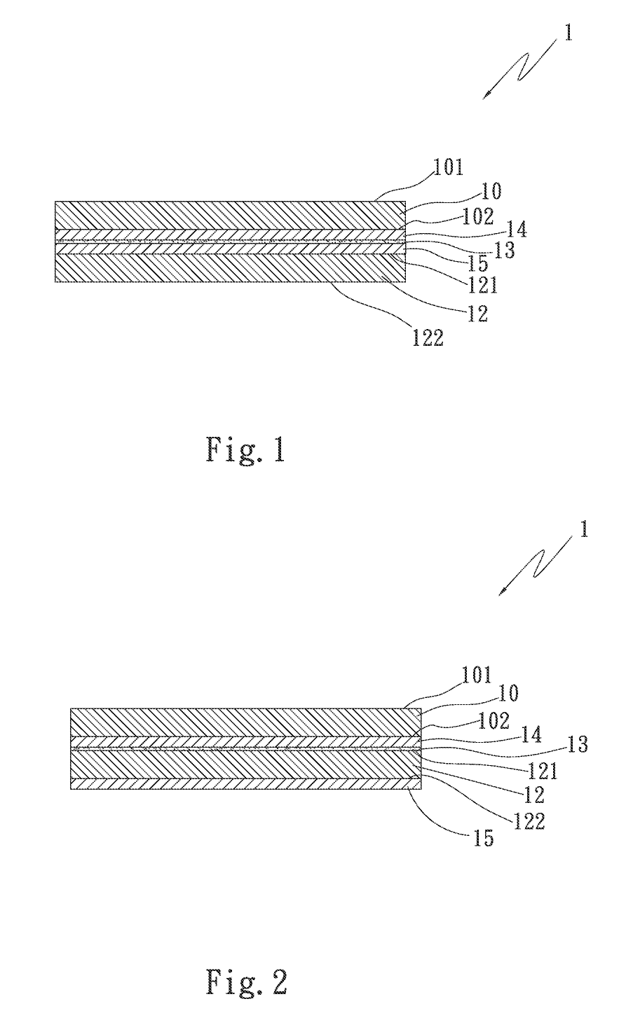

Please refer to FIG. 1, which is a sectional view of a first embodiment of the capacitive touch device of the present invention. According to the first embodiment, the capacitive touch device 1 of the present invention includes a first transparent substrate 10, a second transparent substrate 12 and an adhesive layer 13. The material of the first transparent substrate 10 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the first transparent substrate 10 is, but not limited to, glass for illustration purposes only.

The first transparent substrate 10 has a first side 101 and a second side 102 opposite to the first side 101. A first conductive layer 14 is disposed on the second side 102. The first conductive layer 14 is selected from a group consisting of indium tin oxide (ITO) coating and antimony tin oxide (ATO) coating. The first conductive layer 14 is formed on the second side 102 by means of gelatinization, plating, evaporation or sputtering. In this embodiment, the first conductive layer 14 is formed on the second side 102 by means of, but not limited to, sputtering.

Please further refer to FIG. 1. As the first transparent substrate 10, the material of the second transparent substrate 12 is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC). In this embodiment, the material of the second transparent substrate 12 is, but not limited to, glass for illustration purposes only.

The second transparent substrate 12 has a third side 121 and a fourth side 122 opposite to the third side 121. The third side 121 faces the second side 102. A second conductive layer 15 is disposed on the third side 121. As the first conductive layer 14, the second conductive layer 15 is selected from a group consisting of indium tin oxide (ITO) coating and antimony tin oxide (ATO) coating. The second conductive layer 15 is formed on the third side 121 by means of gelatinization, plating, evaporation or sputtering. In this embodiment, the second conductive layer 15 is formed on the third side 121 by means of, but not limited to, sputtering.

The adhesive layer 13 is selected from a group consisting of optical clear adhesive (OCA) and optical clear resin (OCR). The adhesive layer 13 is disposed between the first transparent substrate 10 and the second transparent substrate 12. That is, one side of the adhesive layer 13 is correspondingly adhered to the second conductive layer 15, while the other side of the adhesive layer 13 is correspondingly adhered to the first conductive layer 14. Accordingly, the first and second transparent substrates 10, 12 are integrally connected with each other via the adhesive layer 13.

By means of the design of the capacitive touch device 1 of the present invention, the total thickness of the touch device is greatly reduced. Moreover, the manufacturing cost is greatly lowered.

Please now refer to FIG. 2, which is a sectional view of a second embodiment of the capacitive touch unit of the present invention. The second embodiment is substantially identical to the first embodiment in structure and connection relationship and thus will not be repeatedly described hereinafter. The second embodiment is different from the first embodiment in that the second conductive layer 15 is disposed on the fourth side 122 of the second transparent substrate 12 instead of the third side 121. The second conductive layer 15 is formed on the fourth side 122 by means of gelatinization, plating, evaporation or sputtering. In this embodiment, the second conductive layer 15 is formed on the fourth side 122 by means of, but not limited to, sputtering.

One side of the adhesive layer 13 is correspondingly adhered to the third side 121, while the other side of the adhesive layer 13 is correspondingly adhered to the first conductive layer 14. Accordingly, the first and second transparent substrates 10, 12 are integrally connected with each other via the adhesive layer 13. By means of the above arrangement of the capacitive touch device 1 of the present invention, the manufacturing cost is lowered and the total thickness of the touch device is greatly reduced.

According to the above, in comparison with the conventional touch device, the present invention has the following advantages:
1. The manufacturing cost is lowered.
2. The total thickness of the touch device is greatly reduced.

The above embodiments are only used to illustrate the present invention, not intended to limit the scope thereof. It is understood that many changes and modifications of the above embodiments can be made without departing from the spirit of the present invention. The scope of the present invention is limited only by the appended claims.

What is claimed is:

1. A capacitive touch device comprising:
a first transparent substrate having a first side and a second side opposite to the first side, a first conductive layer being disposed on the second side;
a second transparent substrate having a third side and a fourth side opposite to the third side, a second conductive layer being selectively disposed on the third side or the fourth side; and
an adhesive layer disposed between the first transparent substrate and the second transparent substrate for connecting the first and second transparent substrates with each other.

2. The capacitive touch device as claimed in claim 1, wherein the second conductive layer is formed on the third side, one side of the adhesive layer being correspondingly adhered to the second conductive layer, while the other side of the adhesive layer being correspondingly adhered to the first conductive layer.

3. The capacitive touch device as claimed in claim 1, wherein the second conductive layer is formed on the fourth side, one side of the adhesive layer being correspondingly adhered to the third side, while the other side of the adhesive layer being correspondingly adhered to the first conductive layer.

4. The capacitive touch device as claimed in claim 1, wherein the material of the first and second transparent substrates is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA), and cycloolefin copolymer (COC).

5. The capacitive touch device as claimed in claim 1, wherein the first and second conductive layers are selected from a group consisting of indium tin oxide (ITO) coatings and antimony tin oxide (ATO) coatings.

6. The capacitive touch device as claimed in claim 2, wherein the first and second conductive layers are respectively formed on the second side and the third side by means of gelatinization, plating, evaporation or sputtering.

7. The capacitive touch device as claimed in claim 3, wherein the first and second conductive layers are respectively formed on the second side and the fourth side by means of gelatinization, plating, evaporation or sputtering.

8. The capacitive touch device as claimed in claim 2, wherein the adhesive layer is selected from a group consisting of optical clear adhesive (OCA) and optical clear resin (OCR).
